(19) United States
(12) Patent Application Publication
(10) Pub. No.: US 2012/0199968 A1
(43) Pub. Date: Aug. 9, 2012

(54) SEMICONDUCTOR PACKAGE

(75) Inventors: Sang-wook PARK, Hwaseong-si (KR); Ho-geon Song, Suwon-si (KR); Kwang-yong LEE, Anyang-si (KR)

(73) Assignee: SAMSUNG ELECTRONICS CO., LTD., Suwon-si (KR)

(21) Appl. No.: 13/348,020

(22) Filed: Jan. 11, 2012

(30) Foreign Application Priority Data
Feb. 9, 2011 (KR) 10-2011-0011616

(51) Int. Cl. H01L 23/498; H01L 23/48

(52) U.S. Cl. 257/737; 257/774; 257/E23.068; 257/E23.011

(57) ABSTRACT

A semiconductor package and method of manufacturing thereof are provided. The package includes: a substrate; a first metal wire on a top surface of the substrate; a first semiconductor chip disposed on the substrate; a first insulation layer which covers the first semiconductor chip and at least a part of the substrate; a second metal wire formed on a top surface of the first insulation layer; a first via formed in the first insulation layer, wherein the first via electrically connects the second metal wire and the first metal wire; and a second semiconductor chip disposed on the second metal wire, wherein the second semiconductor chip is electrically connected to the second metal wire.

### CROSS-REFERENCE TO RELATED APPLICATIONS

This application claims priority from Korean Patent Application No. 10-2011-0011616, filed on Feb. 9, 2011, in the Korean Intellectual Property Office, the disclosure of which is incorporated herein in its entirety by reference.

### BACKGROUND

In general, a plurality of semiconductor chips may be formed by performing various semiconductor-forming processes on a wafer. For example, a semiconductor package may be formed by performing a packaging process on the wafer in order to mount the semiconductor chips on a printed circuit board (PCB). The semiconductor package may include a semiconductor chip, a PCB on which the semiconductor chip is mounted, a bonding wire or a bump that electrically connects the semiconductor chip and the PCB, and a sealing member that seals the semiconductor chip. Meanwhile, the semiconductor package tends toward an ultra-small sized module according to high integration capacity of the semiconductor chip. However, existing semiconductor packages are complex and expensive. A better semiconductor package and method for manufacturing thereof is needed.

### SUMMARY

Apparatuses and methods consistent with the present inventive concept relate to a semiconductor package, and more particularly, to a semiconductor package that (a) is easily manufactured, (b) reduces manufacturing cost and (c) promptly processes data.

One or more exemplary embodiments may overcome the above disadvantages and other disadvantages not described above. However, it is understood that one or more exemplary embodiment are not required to overcome the disadvantages described above, and may not overcome any of the problems described above.

According to an aspect of an exemplary embodiment there is provided a semiconductor package including: a substrate; a first metal wire on a top surface of the substrate; a first semiconductor chip disposed on the substrate; a first insulation layer which covers the first semiconductor chip and at least a part of the substrate; a second metal wire formed on a top surface of the first insulation layer; a first via formed in the first insulation layer, wherein the first via electrically connects the second metal wire and the first metal wire; and a second semiconductor chip disposed on the second metal wire, wherein the second semiconductor chip is electrically connected to the second metal wire.

The semiconductor package may further include: a second via formed in the first insulation layer, wherein the second via electrically connects the first semiconductor chip and the second metal wire.

The first semiconductor chip may include: a non-active surface comprising an adhesive layer, wherein the adhesive layer faces the substrate; and an active surface comprising a bonding pad, wherein the bonding pad is electrically connected to the second metal wire through the second via.

The bonding pad may be plated with an electro less Ni plating.

The semiconductor package may further include a solder metal on the electroless Ni plating.

The electroless Ni plating may have a thickness of about 5 μm.

The solder metal may have a thickness of about 20 μm.

The second semiconductor chip may include: a bonding pad formed in an active surface of the second semiconductor chip; and a bump, which electrically connects the bonding pad to the second metal wire and which is adhered to the second metal wire.

The bump may include a copper filler and a solder cap.

The semiconductor package may further include: a second insulation layer which covers the second semiconductor chip and at least a part of the second metal wire; a third metal wire formed on a top surface of the second insulation layer; and a third via formed in the second insulation layer, wherein the third via electrically connects the third metal wire and the second metal wire.

The semiconductor package may further include: a fourth via formed in the second insulation layer, wherein the fourth via electrically connects the second semiconductor chip and the third metal wire.

The second semiconductor chip may include: a non-active surface comprising an adhesive layer, wherein the adhesive layer faces the second metal wire; and an active surface comprising a bonding pad, wherein the bonding pad is electrically connected to the third metal wire through the fourth via.

The second semiconductor chip may include: a non-active surface comprising an adhesive layer, wherein the adhesive layer faces the second metal wire; and an active surface comprising a bonding pad, wherein the bonding pad is electrically connected to the second metal wire through a bonding wire.

The second metal wire may be made of Ni and Cu or of Cu.

The semiconductor package may further include: a third semiconductor chip electrically connected to the third metal wire and disposed on the third metal wire; a third insulation layer which covers the third semiconductor chip and at least a part of the third metal wire; a fourth metal wire formed on a top surface of the third insulation layer; and a fifth via formed in the third insulation layer, wherein the fifth via electrically connects the fourth metal wire and the third metal wire.

A portion of the first metal wire may be disposed between the first insulation layer and the part of the substrate covered by the first insulation layer.

According to an aspect of an exemplary embodiment there is provided a semiconductor package including: a substrate; a metal wire formed on a top surface of the substrate; a first semiconductor chip disposed on at least a portion of a top surface of the metal wire; a first insulation layer formed to cover the first semiconductor chip and at least a part of the substrate, wherein the first insulation layer is formed so that the first semiconductor chip is embedded in the first insulation layer; a second semiconductor chip disposed on the first insulation layer and electrically connected to the metal wire; and a via formed in the first insulation layer, wherein the via electrically connects the first semiconductor chip to the metal wire.

According to an aspect of an exemplary embodiment there is provided a method of manufacturing a semiconductor package, the method including: forming a first metal wire on a top surface of a substrate; disposing a first semiconductor chip on the substrate; forming a bonding pad on a top surface of the first semiconductor chip; forming a first insulation layer to cover the first semiconductor chip and at least a part of the substrate; forming a second metal wire on a top surface of the first insulation layer; forming a first via in the first insulation layer to electrically connect the second metal wire and the first metal wire; and disposing a second semiconductor chip on the second metal wire, wherein the second semiconductor chip is electrically connected to the second metal wire.

The method may further include: forming a second via in the first insulating layer to electrically connect the second metal wire and the first semiconductor chip.

### BRIEF DESCRIPTION OF THE DRAWINGS

Exemplary embodiments will be more clearly understood from the following detailed description taken in conjunction with the accompanying drawings in which:

FIG. 1 is a cross-sectional view illustrating a semiconductor package according to an exemplary embodiment;

FIG. 2 is an image showing a formation of a second via hole with respect to content of a coloring agent and a filler according to an exemplary embodiment;

FIG. 3 is a cross-sectional view illustrating a semiconductor package according to another exemplary embodiment;

FIG. 4 is a cross-sectional view illustrating a semiconductor package according to another exemplary embodiment;

FIG. 5 is a cross-sectional view illustrating a semiconductor package according to another exemplary embodiment;

FIG. 6 is a cross-sectional view illustrating a semiconductor package according to another exemplary embodiment;

FIG. 7 is a cross-sectional view illustrating a semiconductor package according to another exemplary embodiment;

FIGS. 8 through 12 are cross-sectional views illustrating a method of manufacturing a semiconductor package according to an exemplary embodiment;

FIGS. 13 through 16 are cross-sectional views illustrating a method of manufacturing a semiconductor package according to an exemplary embodiment;

FIGS. 17 and 18 are cross-sectional views illustrating a method of manufacturing a semiconductor package according to an exemplary embodiment;

FIGS. 19 through 21 are cross-sectional views illustrating a method of manufacturing a semiconductor package according to an exemplary embodiment;

FIGS. 22 through 25 are cross-sectional views illustrating a method of manufacturing a semiconductor package according to an exemplary embodiment;

FIGS. 26 and 27 are cross-sectional views illustrating a method of manufacturing a semiconductor package according to an exemplary embodiment; and

FIG. 28 is a block diagram of an electrical and electronic apparatus, examples of which include the semiconductor packages of FIGS. 1 and 3 through 7 according to an exemplary embodiment.

### DETAILED DESCRIPTION OF THE EXEMPLARY EMBODIMENTS

Exemplary embodiments will now be described more fully with reference to the accompanying drawings. It will also be understood that when a layer is referred to as being “on” another layer or substrate, it can be directly on the other layer or substrate, or intervening layers may also be present. In the drawings, the thicknesses of layers and regions are exaggerated for clarity and portions that have nothing to do with the descriptions are omitted. Like reference numerals in the drawings denote like elements. The terminology used therein is for the purpose of describing particular exemplary embodiments only and is not intended to be limiting.

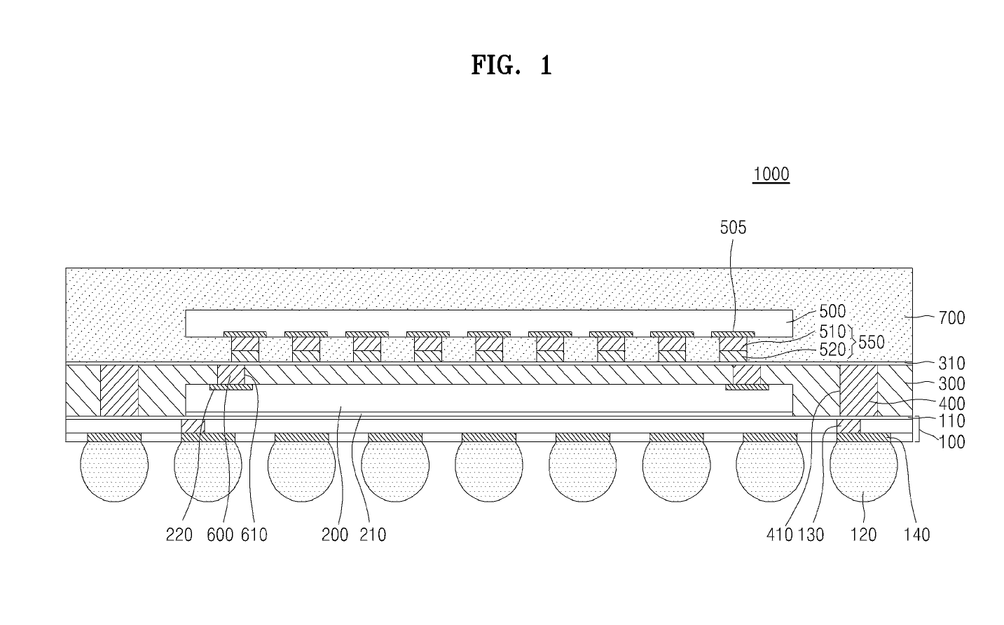

FIG. 1 is a cross-sectional view illustrating a semiconductor package 1000 according to an exemplary embodiment.

Referring to FIG. 1, the semiconductor package 1000 may include a substrate 100, a first semiconductor chip 200, a first insulation layer 300, a second metal wire 310, a first via 400, and a second semiconductor chip 500. The semiconductor chip 1000 may further include a second via 600 and/or a sealing member 700.

The substrate 100 may include a top surface and a bottom surface. The top surface may include the first metal wire 110. The first metal wire 110 is a circuit pattern formed on the substrate 100. The circuit pattern may be formed by using a metal wire such as copper.

The substrate 100 may include an external connection terminal 120 in the bottom surface thereof, and may connect the semiconductor package 1000 to the outside through the external connection terminal 120. The substrate 100 may be, for example, a PCB substrate. The external connection terminal 120 may be a solder ball. The solder ball may be formed in a ball land 140 of the bottom surface of the substrate 100, and may be electrically connected to the first metal wire 110 through a via 130 formed inside the substrate 100.

The first semiconductor chip 200 has an active surface and a non-active surface facing the active surface. The first semiconductor chip 200 may be disposed on the substrate 100. An adhesive layer 210 facing the substrate 100 may be formed in the non- active surface of the first semiconductor chip 200. A bonding pad 220 may be formed in the active surface.

The bonding pad 220 may be formed of a metal such as aluminium (Al), copper (Cu), silver (Ag), or gold (Au), etc., and may act as a stop layer during a process of forming a second via hole 610. A laser drilling process may be used for the process of forming the second via hole 610.

The bonding pad 220 may be formed by plating electro less Ni or by plating electroless Ni and coating a solder metal on the plated electro less Ni. The plated electroless Ni may have a thickness of about 5 μm, and the solder metal may have a thickness of about 20 μm. By plating the bonding pad 220 with electroless Ni or coating the solder metal on the plated electroless Ni, the active surface of the first semiconductor chip 200 may be prevented from being collapsed during the laser drilling process of forming the second via hole 610 to electrically connect the active surface of the first semiconductor chip 200 and the second metal wire 310. As used herein, the term “about” means approximately.

When the solder metal is coated on the plated electroless Ni, since energy may be excessively used enough to melt the solder metal during the laser drilling process, a residual of the first insulation layer 300 may not remain on the bonding pad 220 during the process of forming the second via hole 610.

Accordingly, a desmear process of removing the residual of the first insulation layer 300 from the bonding pad 220 may be unnecessary, which reduces processing cost and prevents a harmful environmental element caused by the desmear process.

The first via 400 may be formed in the first insulation layer 300, and may electrically connect the second metal wire 310 and the first metal wire 110. The first via 400 may be formed by forming the first via hole 410 and filling the first via hole 410 with a conductive material. The conductive material may use Cu, Al, Ag, Au, Ni, and the like, and may be formed by using sputtering, a chemical vapour deposition, or electroplating. The first via hole 410 may be formed by using a mechanical drill process.

The semiconductor package 1000 may further include the second via 600. The second via 600 may be formed in the first insulation layer 300, and may electrically connect the first semiconductor chip 200 and the second metal wire 310. The second via 600 may be formed by forming the second via hole 610 and filling the second via hole 610 with a conductive material. The conductive material may use Cu, Al, Ag, Au, Ni, and the like, and may be formed by using sputtering, a chemical vapour deposition, or electroplating. The second via hole 610 may be formed by using the laser drilling process.

The first insulation layer 300 may cover the first semiconductor chip 200 and at least a part of the substrate 100. The second metal wire 310 may be formed on a top surface of the first insulation layer 300. The first insulation layer 300 can perform a drill process of forming the via holes 410 and 610 in desired predetermined positions by recognizing a top pattern of the first semiconductor chip 200 or a circuit pattern of the first metal wire 110 in a visible ray region, and may use a transparent material. For example, an Ajinomoto Build-Up Film (ABF, e.g., epoxy resin) may be used as the first insulation layer 300. However, a material of the first insulation layer 300 is not limited thereto.

Laser light energy is used during the process of forming the second via hole 610 through the laser drilling process. If appropriate laser energy is not absorbed into the first insulation layer 300, the second via hole 610 is not formed. Thus, to form the desired second via hole 610, a coloring agent may be added to control transmission and scattering of the laser. The coloring agent may use carbon black, but is not limited thereto.

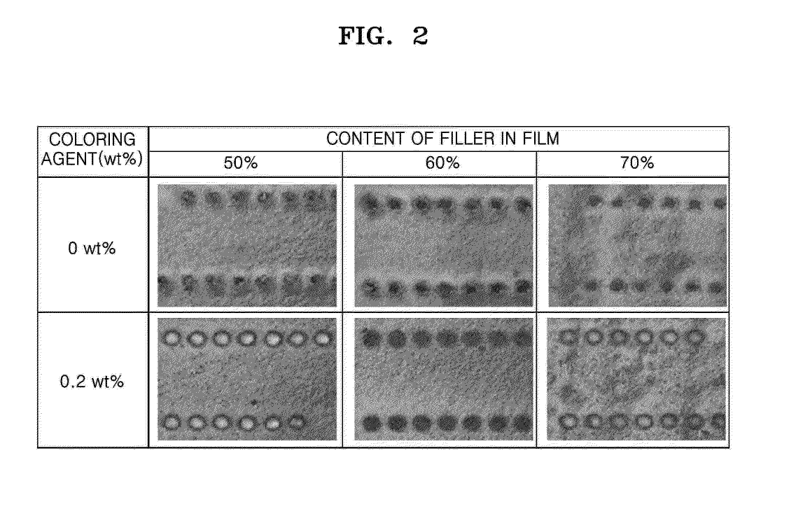

FIG. 2 is an image showing a formation of the second via hole 610 with respect to content of a coloring agent and a filler according to an exemplary embodiment.

Referring to FIG. 2, the formation of the second via hole 610 varies with respect to the content of the filler, and greatly varies with respect to the weight % of the coloring agent. The filler such as silica may be used in the first insulation layer 300. If a coloring agent having 0.2 weight % is used, the second via hole 610 in a desired shape is formed.

The second metal wire 310 is a circuit pattern formed on the top surface of the first insulation layer 300. A Cu metal wire may be formed by forming a seed layer (not shown) in the top surface of the first insulation layer 300, coating a photosensitive resist on the seed layer (not shown), patterning the photosensitive resist to open a position where a circuit is formed, forming a copper plating layer, and removing the photosensitive resist. Also, heterogeneous metal wires of Ni/Cu (i.e., Ni and Cu) may be formed through electroless Ni plating and electrolytic Cu plating. A thickness of the second metal wire 310 may be at least 5 μm.

The second semiconductor chip 500 may be electrically connected to the second metal wire 310, and may be disposed on the second metal wire 310.

Referring to FIG. 1, the second semiconductor chip 500 may include a bonding pad 505 formed in an active surface thereof, and a bump 550 that electrically connects the bonding pad 505 to the second metal wire 310 and is adhered onto the second metal wire 310. The bump 550 may include a solder cap 520 or may include a copper filler 510 and the solder cap 520. The copper filler 510 is included in the bump 550, thereby preventing the bump 550 from being collapsed during a reflow process of disposing the second semiconductor chip 500 on the first insulation layer 300. The bump 550 may have a height greater than 30 μm for a gap filling.

The second semiconductor chip 500 and the second metal wire 310 may be sealed by coating the sealing member 700 like an epoxy molding compound (EMC).

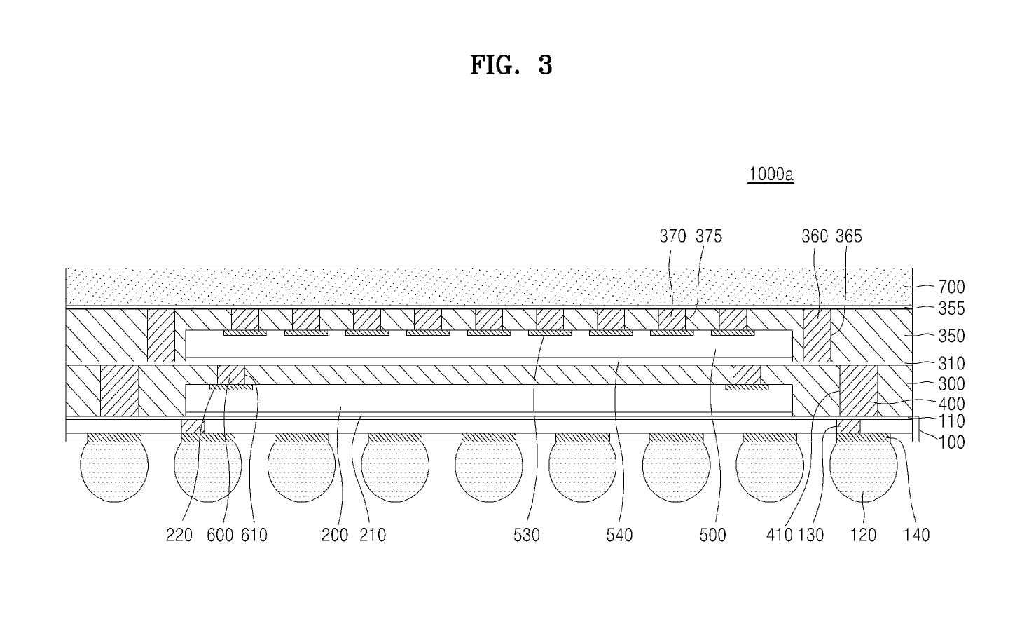

FIG. 3 is a cross-sectional view illustrating a semiconductor package 1000a according to another exemplary embodiment. Differences between the semiconductor package 1000a and the semiconductor package 1000 of FIG. 1 will now be described, and the same description therebetween will not be repeated.

Referring to FIG. 3, the semiconductor package 1000a is different from the semiconductor package 1000 of FIG. 1 in that a non-active surface of the second semiconductor chip 500 faces the second metal wire 310, the second semiconductor chip 500 is embedded in a second insulation layer 350, and vias 360 and 370 are formed in the second insulation layer 350.

The second insulation layer 350 may cover the second semiconductor chip 500 and at least a part of the second metal wire 310. A third metal wire 355 may be formed on a top surface of the second insulation layer 350. The second insulation layer 350 can perform a drilling process of forming via holes 365 and 375 in desired predetermined positions by recognizing a top pattern of the second semiconductor chip 500 or a circuit pattern of the second metal wire 310 in a visible ray region, and may use a transparent material. For example, an ABF (epoxy resin) may be used as the second insulation layer 350. However, a material of the second insulation layer 350 is not limited thereto.

As with the example discussed above, laser light energy is used during the process of forming the fourth via hole 375 through the laser drilling process. If appropriate laser energy is not absorbed into the second insulation layer 350, the fourth via hole 375 is not formed. Thus, to form the desired fourth via hole 375, a coloring agent is added to control transmission and scattering of the laser. The coloring agent may use carbon black, but is not limited thereto. Referring to FIG. 2, the formation of the fourth via hole 375 varies with respect to the content of the filler, and greatly varies with respect to the weight % of the coloring agent. The filler such as silica may be used in the second insulation layer 350. A coloring agent having 0.2 weight % may be used in the second insulation layer 350.

The third metal wire 355 is a circuit pattern formed on the top surface of the second insulation layer 350. A Cu metal wire may be formed by forming a seed layer (not shown) in a top surface of the second insulation layer 350, coating a photosensitive resist on the seed layer (not shown), patterning the photosensitive resist to open a position where a circuit is formed, forming a copper plating layer, and removing the photosensitive resist. Also, heterogeneous metal wires of Ni/Cu may be formed through electroless Ni plating and electrolytic Cu plating. A thickness of the third metal wire 355 may be at least 5 μm.

The third via 360 may be formed in the second insulation layer 350, and may electrically connect the third metal wire 355 and the second metal wire 310. The third via 360 may be formed by forming the third via hole 365 and filling the third via hole 365 with a conductive material. The conductive material may use Cu, Al, Ag, Au, Ni, and the like, and may be formed by using sputtering, a chemical vapour deposition, or electroplating. The third via hole 365 may be formed by using a mechanical drilling process.

The semiconductor package 1000a may further include the fourth via 370. The fourth via 370 may be formed in the second insulation layer 350, and may electrically connect the second semiconductor chip 500 and the third metal wire 355. The fourth via 370 may be formed by forming the fourth via hole 375 and filling the fourth via hole 375 with a conductive material. The conductive material may use Cu, Al, Ag, Au, Ni, and the like, and may be formed by using sputtering, a chemical vapour deposition, or electroplating. The fourth via hole 375 may be formed by using the laser drilling process.

The second semiconductor chip 500 has a non-active surface in which an adhesive layer 540 facing the second metal wire 310 is disposed and an active surface in which the bonding pad 530 electrically connected to the third metal wire 355 through the fourth via 370 is formed.

The bonding pad 530 may be formed of a metal such as aluminium (Al), copper (Cu), silver (Ag), or gold (Au), etc. and may act as a stop layer during a process of forming a fourth via hole 375. A laser drilling process may be used for the process of forming the fourth via hole 375.

The bonding pad 530 may be formed by plating electro less Ni or by plating electroless Ni and coating a solder metal on the plated electro less Ni. The plated electroless Ni may have a thickness of about 5 μm, and the solder metal may have a thickness of about 20 μm. By plating the bonding pad 530 with electroless Ni or coating the solder metal on the plated electro less Ni, the active surface of the second semiconductor chip 500 may be prevented from being damaged during the laser drilling process of forming the fourth via hole 375 to electrically connect the active surface of the second semiconductor chip 500 and the third metal wire 355.

When the solder metal is coated on the plated electroless Ni, since energy may be excessively used enough to melt the solder metal during the laser drilling process, a residual of the second insulation layer 350 may not remain on the bonding pad 530 during the process of forming the fourth via hole 375. Accordingly, a desmear process of removing the residual of the second insulation layer 375 from the bonding pad 530 may be unnecessary, which reduces processing cost and prevents a harmful environmental element caused by the desmear process.

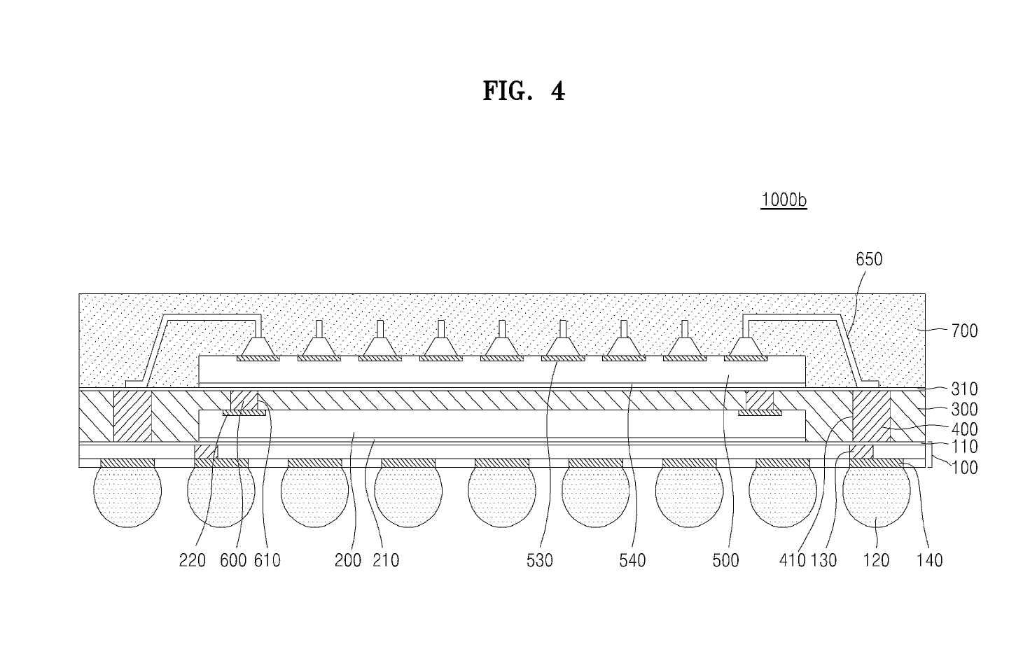

FIG. 4 is a cross-sectional view illustrating a semiconductor package 1000b according to another exemplary embodiment. Differences between the semiconductor package 1000a and the semiconductor package 1000 of FIG. 1 will now be described, and the same description therebetween will not be repeated.

Referring to FIG. 4, the semiconductor package 1000a is different from the semiconductor package 1000 of FIG. 1 in that the non-active surface of the second semiconductor chip 500 faces the second metal wire 310, the bonding pad 530 of the second semiconductor chip 500 is electrically connected to the second metal wire 310 through a bonding wire 650.

The second semiconductor chip 500 has a non-active surface in which the adhesive layer 540 facing the second metal wire 310 is disposed and an active surface in which the bonding pad 530 electrically connected to the second metal wire 310 through the bonding wire 650 is formed.

The bonding pad 530 may be formed of a metal such as aluminium (Al), copper (Cu), silver (Ag), or gold (Au), etc.

The second semiconductor chip 500, the second metal wire 310, and the bonding wire 650 may be sealed by coating the sealing member 700 such as an EMC.

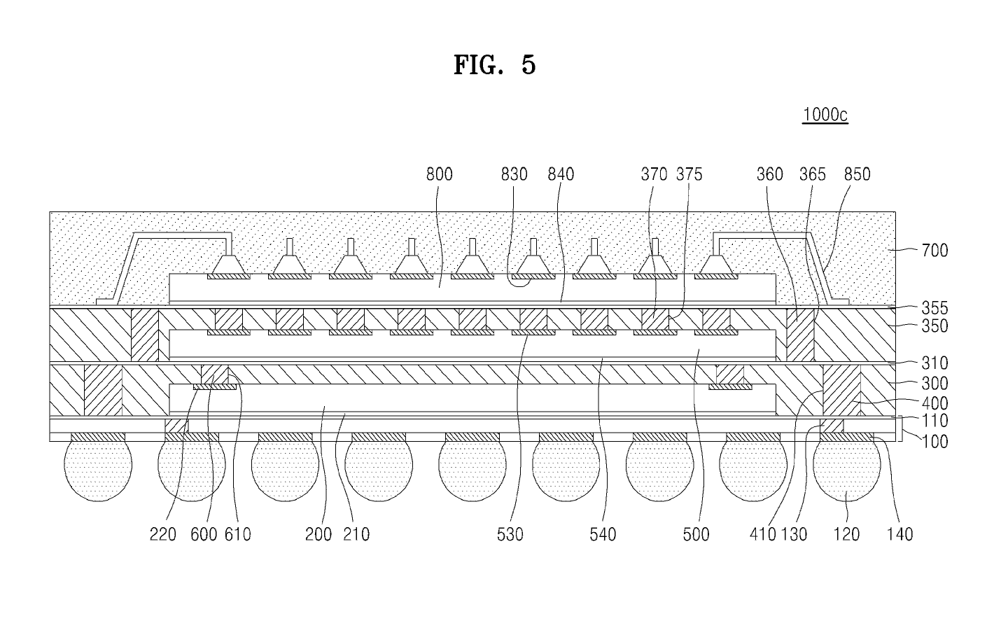

FIG. 5 is a cross-sectional view illustrating a semiconductor package 1000c according to another exemplary embodiment. Differences between the semiconductor package 1000c and the semiconductor package 1000a of FIG. 3 will now be described, and the same description therebetween will not be repeated.

Referring to FIG. 5, the semiconductor package 1000a is different from the semiconductor package 1000a of FIG. 3 in that a third semiconductor chip 800 is disposed on the third metal wire 355, and a bonding pad 830 of the third semiconductor chip 800 is electrically connected to the third metal wire 355 through a bonding wire 850.

The third semiconductor chip 800 has a non-active surface in which an adhesive layer 840 facing the third metal wire 355 is disposed and an active surface in which the bonding pad 830 electrically connected to the third metal wire 355 through the bonding wire 850 is formed.

The third semiconductor chip 800, the third metal wire 355, and the bonding wire 850 may be sealed by coating the sealing member 700 such as an EMC.

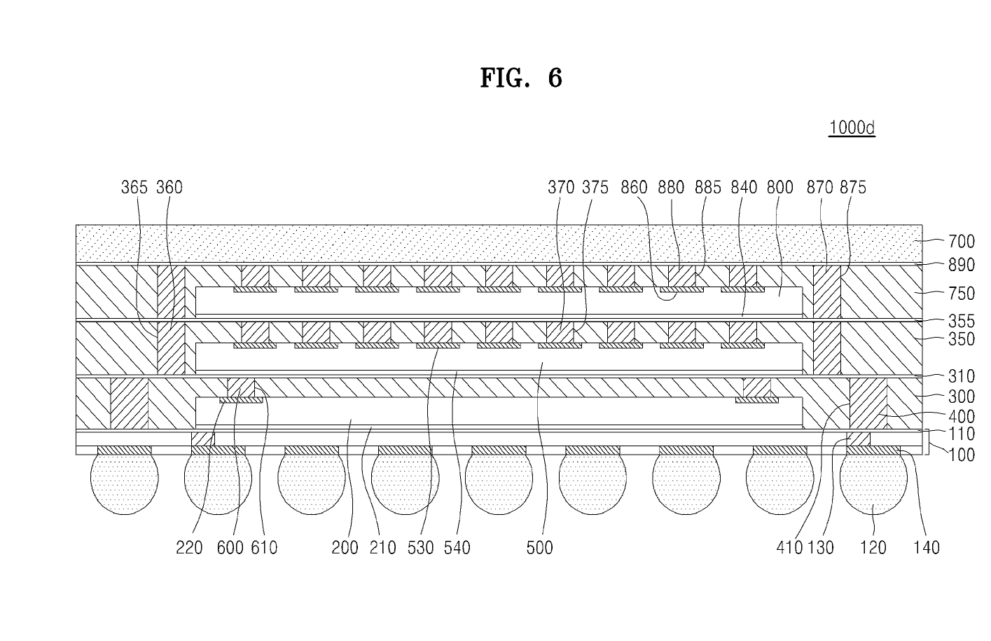

FIG. 6 is a cross-sectional view illustrating a semiconductor package 1000d according to another exemplary embodiment. Differences between the semiconductor package 1000d and the semiconductor package 1000a of FIG. 3 will now be described, and the same description therebetween will not be repeated.

Referring to FIG. 6, the semiconductor package 1000d in which the third semiconductor chip 800 is further stacked is different from the semiconductor package 1000a of FIG. 3 in that a non-active surface of the third semiconductor chip 800 faces the third metal wire 355, the third semiconductor chip 800 is embedded in a third insulation layer 750, and a via is formed in the third insulation layer 750.

The third insulation layer 750 may cover the third semiconductor chip 800 and at least a part of the third metal wire 355, and may include a fourth metal wire 890 on a top surface of the third insulation layer 750.

The third insulation layer 750 can perform a drilling process of forming via holes 875 and 885 in desired predetermined positions by recognizing a top pattern of the third semiconductor chip 800 or a circuit pattern of the third metal wire 355 in a visible ray region, and may use a transparent material. For example, an ABF (epoxy resin) may be used as the third insulation layer 750. However, a material of the third insulation layer 750 is not limited thereto.

Again, laser light energy is used during the process of forming the sixth via hole 885 through the laser drilling process. If appropriate laser energy is not absorbed into the third insulation layer 750, the sixth via hole 885 is not formed. Thus, to form the desired sixth via hole 885, a coloring agent is added to control transmission and scattering of the laser. The coloring agent may use carbon black, but is not limited thereto. Referring to FIG. 2, the formation of the fourth via hole 375 varies with respect to the content of the filler, and greatly varies with respect to the weight % of the coloring agent. The filler such as silica may be used in the third insulation layer 750. A coloring agent having 0.2 weight % may be used in the third insulation layer 750.

The fourth metal wire 890 is a circuit pattern formed on the top surface of the third insulation layer 750. A Cu metal wire may be formed by forming a seed layer (not shown) in a top surface of the third insulation layer 750, coating a photosensitive resist on the seed layer (not shown), patterning the photosensitive resist to open a position where a circuit is formed, forming a copper plating layer, and removing the photosensitive resist. Also, heterogeneous metal wires of Ni/Cu may be formed through electroless Ni plating and electrolytic Cu plating. A thickness of the fourth metal wire 890 may be at least 5 μm.

A fifth via 870 may be formed in the third insulation layer 750, and may electrically connect fourth metal wire 890 and the third metal wire 355. The fifth via 870 may be formed by forming the fifth via hole 875 and filling the fifth via hole 875 with a conductive material. The conductive material may use Cu, Al, Ag, Au, Ni, and the like, and may be formed by using sputtering, a chemical vapour deposition, or electroplating. The fifth via hole 875 may be formed by using a mechanical drilling process.

The semiconductor package 1000d may further include a sixth via 880 that may be formed in the third insulation layer 750, and may electrically connect the third semiconductor chip 800 and the fourth metal wire 890.

The sixth via 880 may be formed by forming the sixth via hole 885 and filling the sixth via hole 885 with a conductive material. The conductive material may use Cu, Al, Ag, Au, Ni, and the like, and may be formed by using sputtering, a chemical vapour deposition, or electroplating. The sixth via hole 885 may be formed by using the laser drilling process.

The third semiconductor chip 800 has a non-active surface in which the adhesive layer 840 facing the third metal wire 355 is disposed and an active surface in which a bonding pad 860 electrically connected to the fourth metal wire 890 through the sixth via 880 is formed.

The bonding pad 860 may be formed of a metal such as aluminium (Al), copper (Cu), silver (Ag), or gold (Au), etc. and may act as a stop layer during a process of forming the sixth via hole 885. A laser drilling process may be used for the process of forming the sixth via hole 885. The bonding pad 860 may be formed by plating electroless Ni or by plating electroless Ni and coating a solder metal on the plated electroless Ni. The plated electroless Ni may have a thickness of about 5 μm, and the solder metal may have a thickness of about 20 μm. By plating the bonding pad 860 with electro less Ni or coating the solder metal on the plated electroless Ni, the active surface of the third semiconductor chip 800 may be prevented from being damaged during the laser drilling process of forming the fifth via hole 875 to electrically connect the active surface of the second semiconductor chip 500 and the fourth metal wire 890.

When the solder metal is coated on the plated electroless Ni, since energy may be excessively used enough to melt the solder metal during the laser drilling process, a residual of the third insulation layer 750 may not remain on the bonding pad 860 during the process of forming the sixth via hole 885. Accordingly, a desmear process of removing the residual of the third insulation layer 750 from the bonding pad 860 may be unnecessary, which reduces processing cost and prevents a harmful environmental element caused by the desmear process.

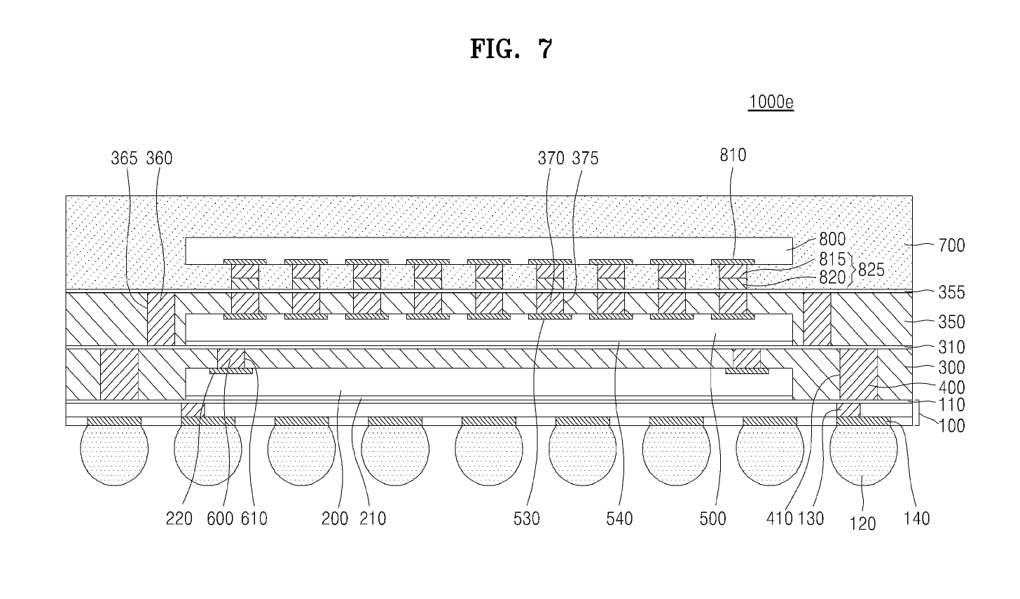

FIG. 7 is a cross-sectional view illustrating a semiconductor package 1000e according to another exemplary embodiment. Differences between the semiconductor package 1000e and the semiconductor package 1000a of FIG. 3 will now be described, and the same description therebetween will not be repeated.

Referring to FIG. 7, the semiconductor package 1000e in which the third semiconductor chip 800 is further stacked is different from the semiconductor package 1000a of FIG. 3 in that the third semiconductor chip 800 including the bump 825 is formed on the third metal wire 355.

The third semiconductor chip 800 may be electrically connected to the third metal wire 355 and may be disposed on the third metal wire 355.

Referring to FIG. 7, the third semiconductor chip 800 may include a bonding pad 810 formed on the active surface thereof and the bump 825 that is electrically connected to the third metal wire 355 and is adhered onto the third metal wire 355.

The bump 825 may include a solder cap 820 or may include a copper filler 815 and the solder cap 820. The copper filler 815 is included in the bump 825, thereby preventing the bump 825 from being collapsed during a reflow process of disposing the third semiconductor chip 800 on the second insulation layer 350. The bump 825 may have a height greater than 30 μm for a gap filling.

The third semiconductor chip 800 and the third metal wire 355 may be sealed by coating the sealing member 700 like an EMC.

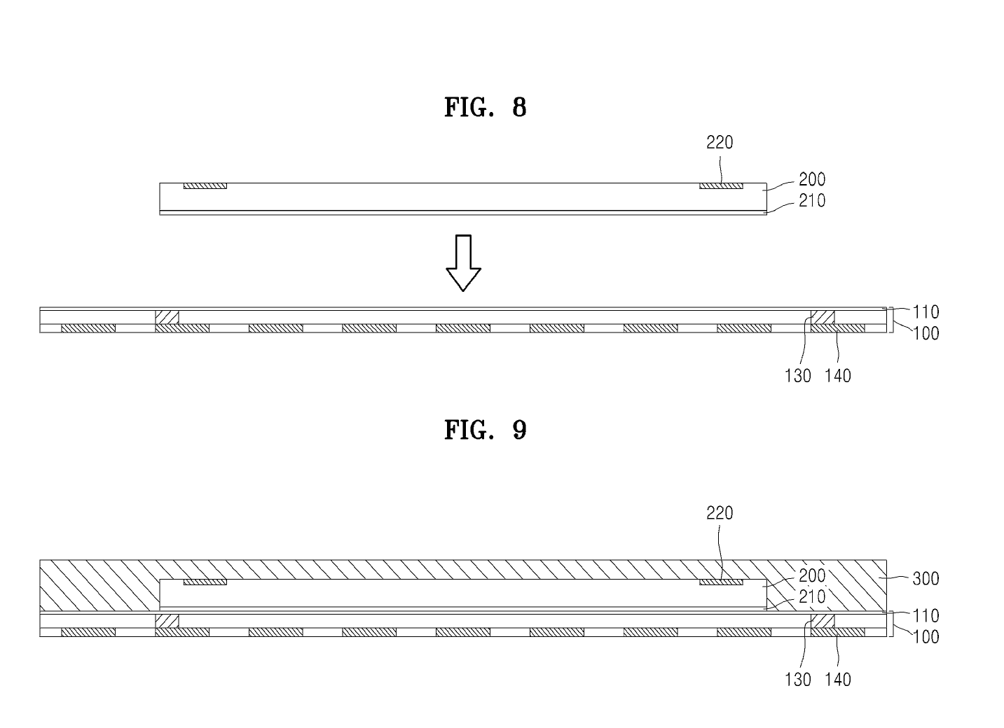

FIGS. 8 through 12 are cross-sectional views illustrating a method of manufacturing a semiconductor package, an example of which is the semiconductor package 1000 of FIG. 1, according to an exemplary embodiment.

Referring to FIG. 8, the first semiconductor chip 200 may be disposed on the substrate 100 having the metal wire 110 formed on a top surface thereof.

The substrate 100 may include the external connection terminal 120 in a bottom surface thereof. The external connection terminal 120 may be a solder ball.

The first semiconductor chip 200 may include the adhesive layer 210 facing the substrate 100 in the non-active surface thereof and the bonding pad 220 in the active surface thereof.

Meanwhile, although the adhesive layer 210 is formed in the non-active surface of the first semiconductor chip 200 according to the thickness of the first semiconductor chip 200 in FIG. 8, the inventive concept is not limited thereto. The first semiconductor chip 200 may be disposed on the substrate 100 on which the adhesive layer 210 is formed.

The bonding pad 220 of the first semiconductor chip 200 may be formed of a metal such as aluminium (Al), copper (Cu), silver (Ag), or gold (Au), etc. as described above and may act as a stop layer during a process of forming the second via hole 610. The bonding pad 220 may be formed by plating electroless Ni or by plating electro less Ni and coating a solder metal on the plated electroless Ni. The plated electroless Ni may have a thickness of about 5 μm, and the solder metal may have a thickness of about 20 μm.

Referring to FIG. 9, the first insulation layer 300 may be formed to cover the first semiconductor chip 200 and at least a part of the substrate 100. The first insulation layer 300 may be formed by laminating an insulation layer and curing the laminated insulation layer. A drilling process can be performed on the first insulation layer for forming the via holes 410 and 610 in desired predetermined positions by recognizing the top pattern of the first semiconductor chip 200 or the circuit pattern of the first metal wire 110 in a visible ray region, and may use a transparent material. For example, an ABF (epoxy resin) may be used as the first insulation layer 300. However, a material of the first insulation layer 300 is not limited thereto.

In the process of forming the second via hole 610 through a laser drilling process, to form the desired second via hole 610 in the first insulation layer 300, a coloring agent is added to control transmission and scattering of laser. The coloring agent may use carbon black, but is not limited thereto. The coloring agent may have about 0.2 weight %.

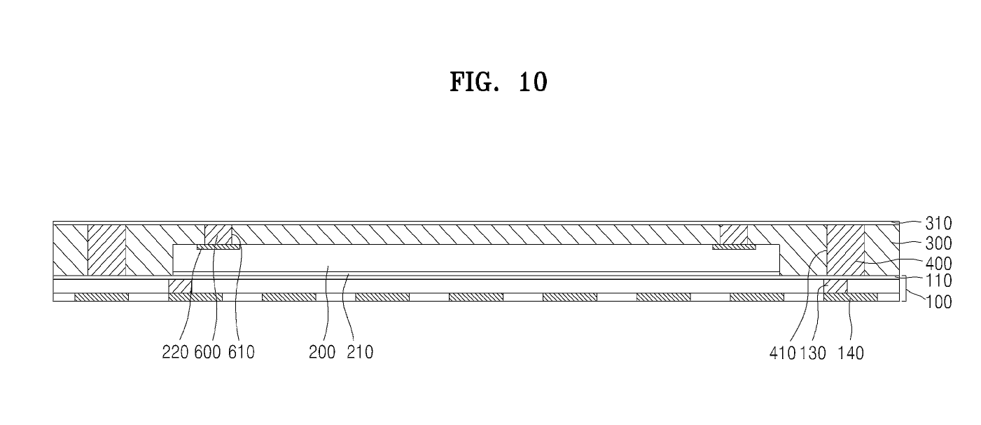

Referring to FIG. 10, the first via hole 410 and the second via hole 610 may be formed in the first insulation layer 300. The first via hole 410 may use a mechanical drilling process. The second via hole 610 may use a laser drilling process. However, the present inventive concept is not limited thereto.

The first insulation layer 300 can recognize the top pattern of the first semiconductor chip 200 or the circuit pattern of the first metal wire 110 in a visible ray region, thereby forming the first and second via holes 410 and 610 in desired predetermined positions.

When the second via hole 610 is formed, since the bonding pad 220 is formed by plating electro less Ni or by plating electroless Ni and coating a solder metal on the plated electroless Ni, the bonding pad 220 acts as a laser stop layer during the laser drilling process, thereby preventing the first semiconductor chip 200 from being damaged.

Then, the first via 400 and the second via 600 may be formed by filling the first via hole 410 and the second via hole 610 with a conductive material. The conductive material may use Cu, Al, Ag, Au, Ni, and the like, and may be formed by using sputtering, a chemical vapour deposition, or electroplating.

Then, the second metal wire 310 may be formed in entire surfaces of the first insulation layer 300, the first via 400, and the second via 600. Thus, the first semiconductor chip 200 and the second semiconductor chip 500 may be electrically connected to each other through the bump 550 and the second via 600, and may be connected to the substrate 100 through the first via 400.

The second metal wire 310 is a circuit pattern formed on entire surfaces of the first insulation layer 300, the first via 400, and the second via 600. A Cu metal wire may be formed by forming a seed layer (not shown) in the entire surfaces of the first insulation layer 300, the first via 400, and the second via 600, coating a photosensitive resist on the seed layer (not shown), patterning the photosensitive resist to open a position where a circuit is formed, forming a copper plating layer, and removing the photosensitive resist.

Also, heterogeneous metal wires of Ni/Cu may be formed through electroless Ni plating and electrolytic Cu plating. A thickness of the second metal wire 310 may be at least 5 μm.

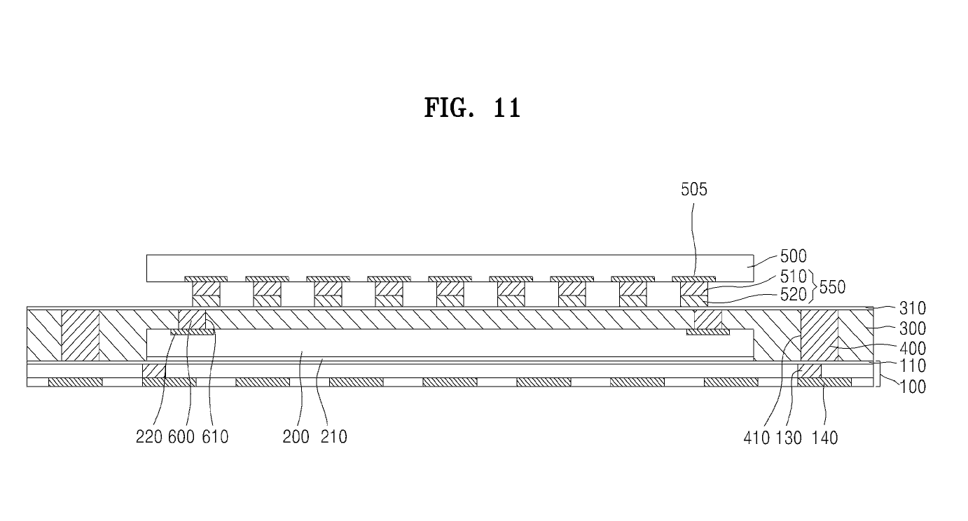

Referring to FIG. 11, the second semiconductor chip 500 may be disposed on the second metal wire 310. The second semiconductor chip 500 may include the bonding pad 505 formed in the active surface thereof, and the bump 550 that electrically connects the bonding pad 505 to the second metal wire 310 and is adhered onto the second metal wire 310. The bump 550 may include the solder cap 520 or may include the copper filler 510 and the solder cap 520. The bump 550 may have a height greater than 30 μm for a gap filling.

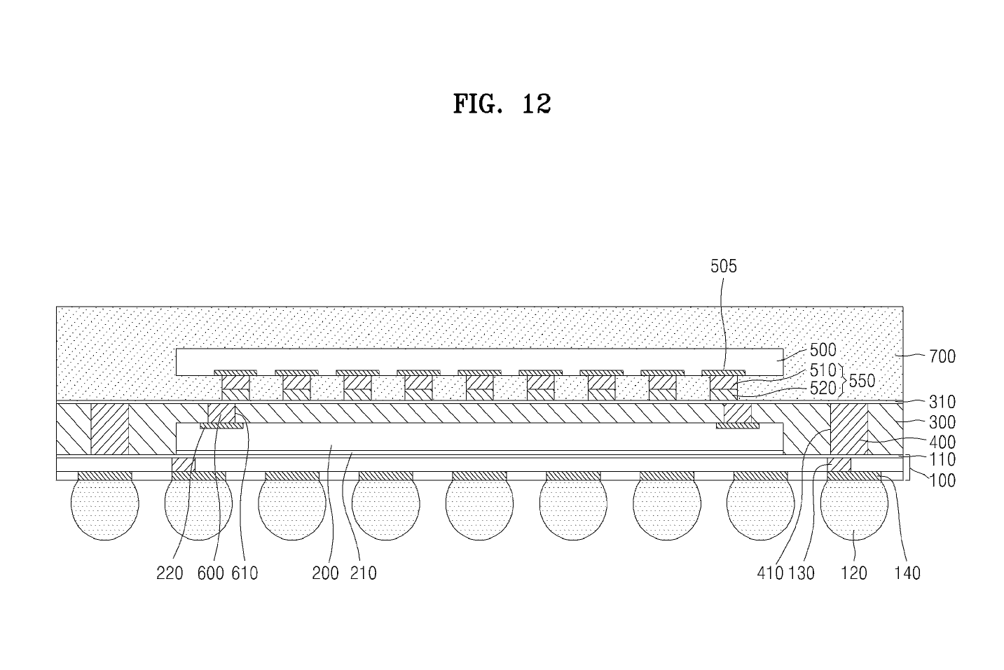

Referring to FIG. 12, the second semiconductor chip 500 and the second metal wire 310 may be sealed by coating the sealing member 600 like an EMC, and may form the external connection terminal 120 like a solder ball in the bottom surface of the substrate 100.

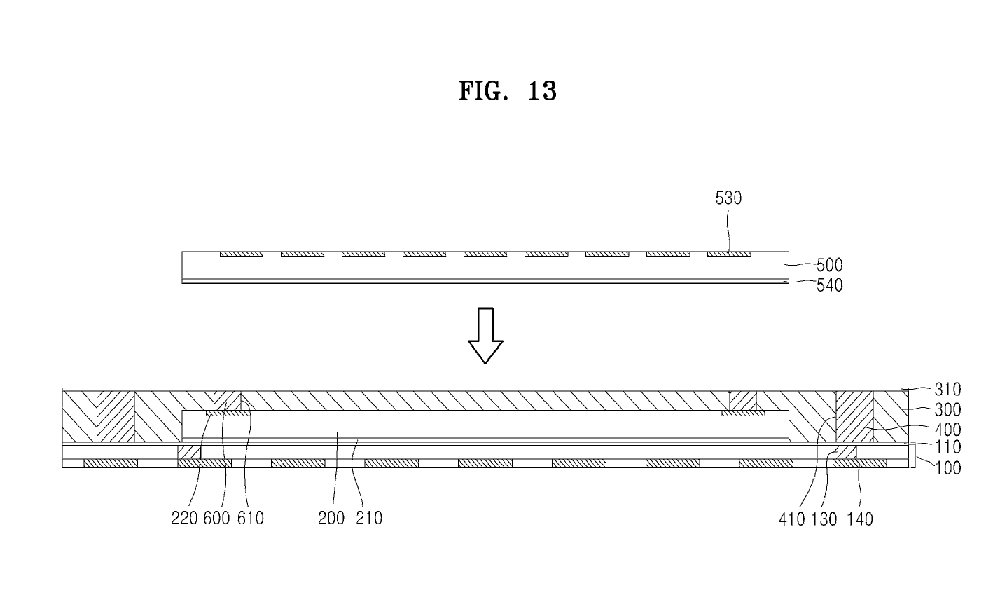

FIGS. 13 through 16 are cross-sectional views illustrating a method of manufacturing the semiconductor package 1000a of FIG. 3 according to an exemplary embodiment. The method of manufacturing the semiconductor package 1000a of FIG. 3 is the same as that described with reference to FIGS. 8 through 10, and thus the same descriptions will not be repeated, and differences therebetween will now be described.

Referring to FIG. 13, the second semiconductor chip 500 may be disposed on the second metal wire 310.

The second semiconductor chip 500 may include the adhesive layer 540 facing the second metal wire 310 in the non-active surface thereof and the bonding pad 530 in the active surface thereof.

Meanwhile, although the adhesive layer 540 is formed in the non-active surface of the second semiconductor chip 500 according to the thickness of the second semiconductor chip 500 in FIG. 13, the inventive concept is not limited thereto. The second semiconductor chip 500 may be disposed on the second metal wire 310 on which the adhesive layer 540 is formed.

The bonding pad 530 of the second semiconductor chip 500 may be formed of a metal such as aluminium (Al), copper (Cu), silver (Ag), or gold (Au), etc. as described above and may act as a stop layer during a process of forming the fourth via hole 375.

The bonding pad 530 may be formed by plating electroless Ni or by plating electroless Ni and coating a solder metal on the plated electro less Ni. The plated electroless Ni may have a thickness of about 5 μm, and the solder metal may have a thickness of about 20 μm.

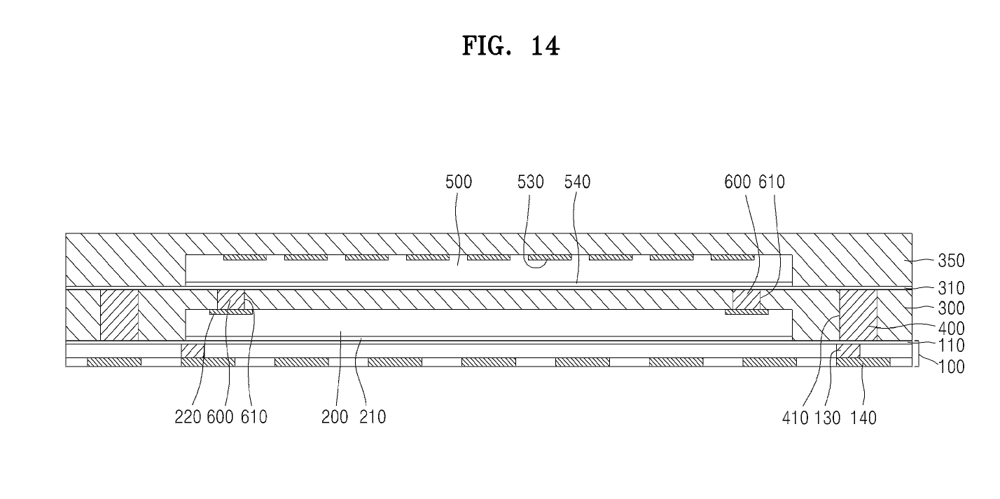

Referring to FIG. 14, the second insulation layer 350 may be formed to cover the second semiconductor chip 500 and at least a part of the second metal wire 310. The second insulation layer 350 may be formed by using the same method as that of forming the first insulation layer 300, and may be formed of the same material as that of the first insulation layer 300.

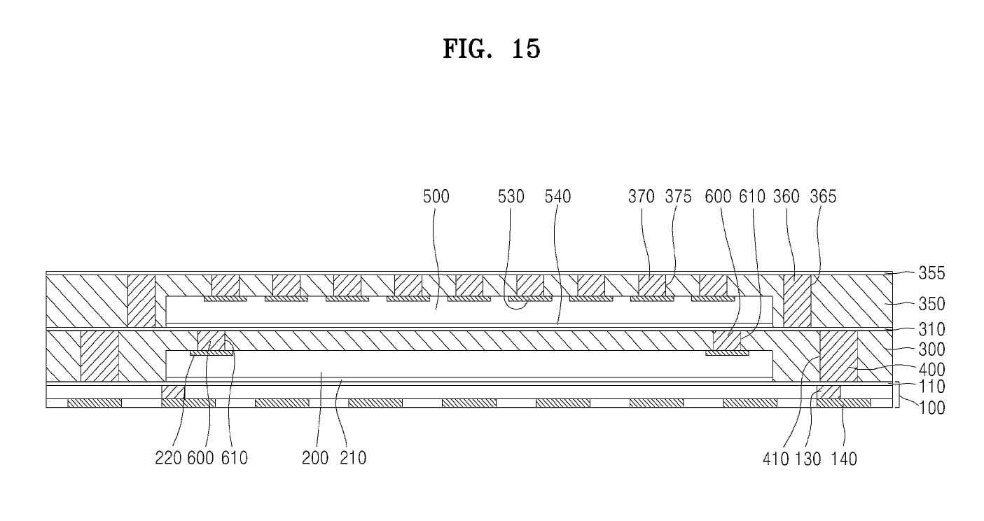

Referring to FIG. 15, the third via hole 365 and the fourth via hole 375 may be formed in the second insulation layer 350. The third via hole 365 may use a mechanical drilling process. The fourth via hole 375 may use a laser drilling process.

When the fourth via hole 375 is formed, since the bonding pad 530 is formed by plating electro less Ni or by plating electroless Ni and coating a solder metal on the plated electroless Ni, the bonding pad 530 acts as a laser stop layer during the laser drilling process, thereby preventing the second semiconductor chip 500 from being damaged.

Then, the third via 360 and the fourth via 370 may be formed by filling the third via hole 365 and the fourth via hole 375 with a conductive material. The conductive material may use Cu, Al, Ag, Au, Ni, and the like, and may be formed by using sputtering, a chemical vapour deposition, or electroplating.

Then, the third metal wire 355 may be formed in entire surfaces of the second insulation layer 350, the third via 360, and the fourth via 370. Thus, the first semiconductor chip 200 and the second semiconductor chip 500 may be electrically connected to the second metal wire 310 through the third via 360 and the fourth via 370. The third metal wire 355 may be formed by using the same method as that of forming the second metal wire 310 described above.

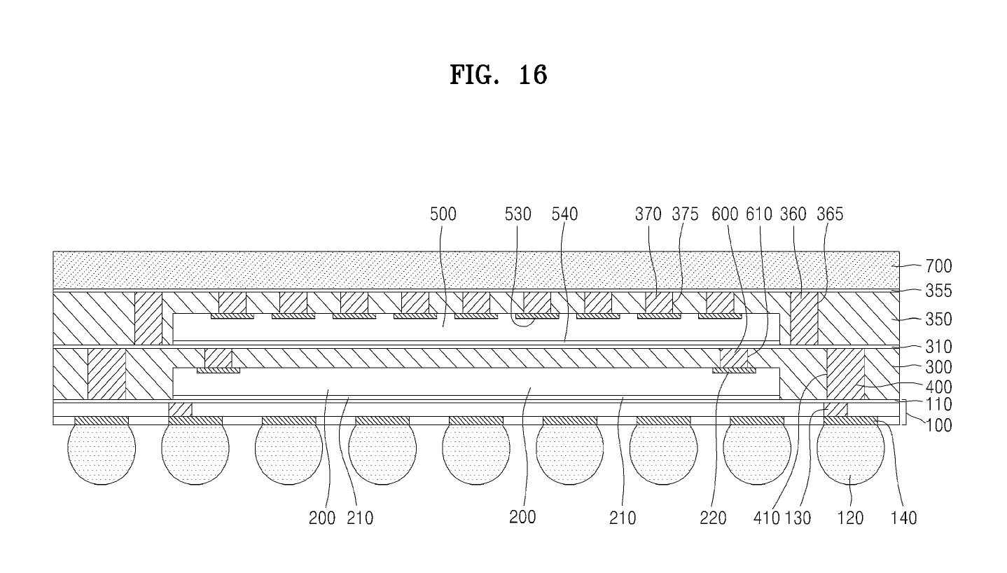

Referring to FIG. 16, the semiconductor package 1000a may be formed by coating the sealing member 700 like an EMC on the third metal wire 355 and forming the external connection terminal 120 like a solder ball in the bottom surface of the substrate 100.

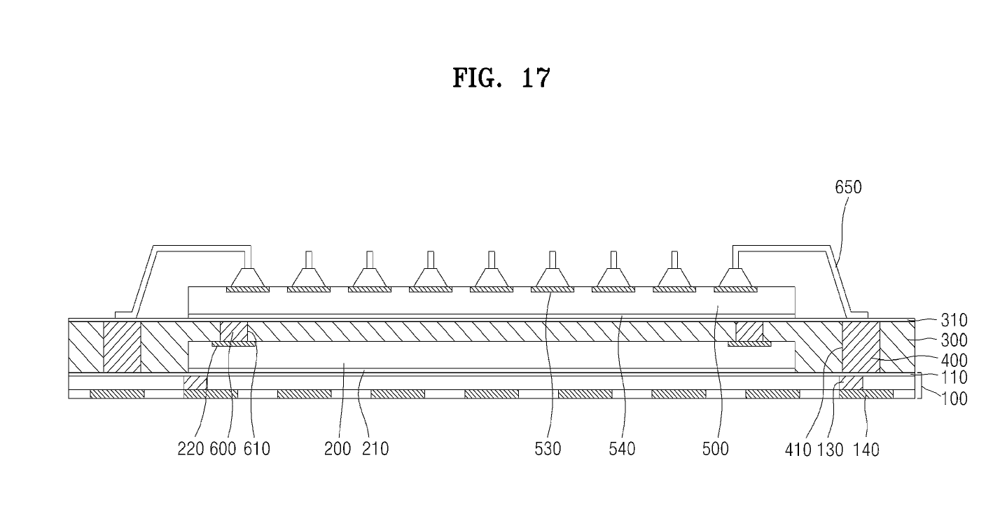

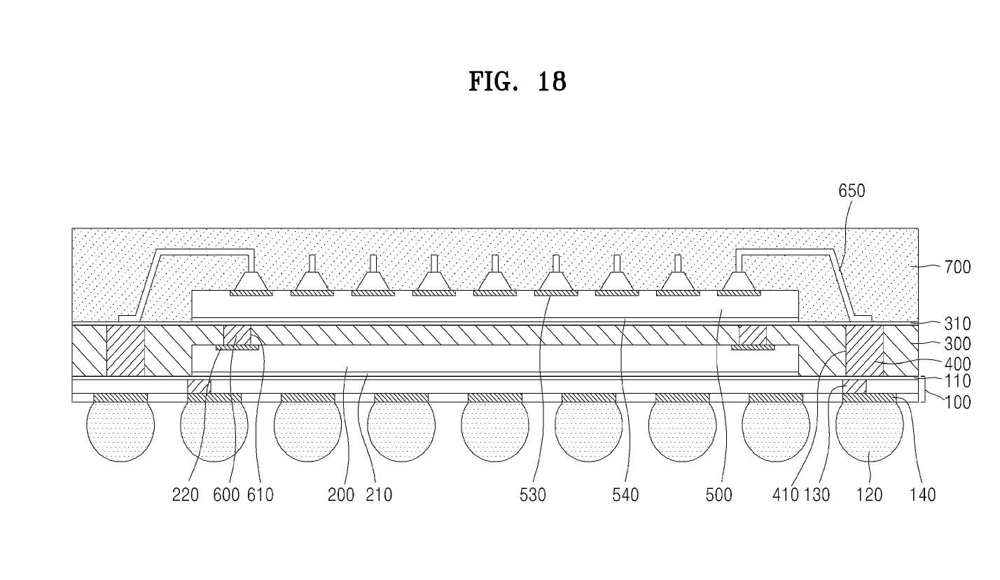

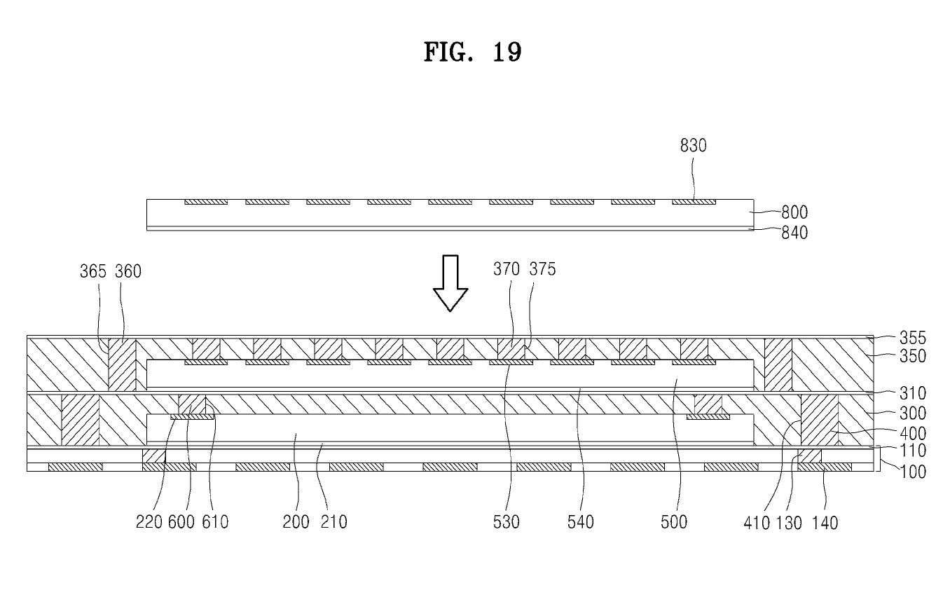

FIGS. 17 and 18 are cross-sectional views illustrating a method of manufacturing the semiconductor package 1000b of FIG. 4 according to an exemplary embodiment. The method of manufacturing the semiconductor package 1000b of FIG. 4 is the same as that of manufacturing the semiconductor package 1000a of FIG. 3 as described with reference to FIGS. 8 through 10, 13, and thus the same descriptions will not be repeated, and differences therebetween will now be described.

Referring to FIG. 17, the bonding wire 650 may be formed between the bonding pad 530 of the second semiconductor chip 500 and the second metal wire 310. The second semiconductor chip 500 may be electrically connected to the second metal wire 310 through the bonding wire 650.

Referring to FIG. 18, the semiconductor package 1000b may be formed by coating the sealing member 700 like an EMC on the second semiconductor chip 500, the second metal wire 310, and the bonding wire 650, and forming the external connection terminal 120 like a solder ball in the bottom surface of the substrate 100.

FIGS. 19 through 21 are cross-sectional views illustrating a method of manufacturing the semiconductor package 1000c of FIG. 5 according to an exemplary embodiment. The method of manufacturing the semiconductor package 1000c of FIG. 5 is the same as that of manufacturing the semiconductor package 1000a of FIG. 3 as described with reference to FIGS. 13 through 15, and thus the same descriptions will not be repeated, and differences therebetween will now be described.

Referring to FIG. 19, the third semiconductor chip 800 may be disposed on the third metal wire 355.

The third semiconductor chip 800 may include the adhesive layer 840 facing the third metal wire 355 in the non-active surface thereof and the bonding pad 830 in the active surface thereof.

Meanwhile, although the adhesive layer 840 is formed in the non-active surface of the third semiconductor chip 800 according to the thickness of the third semiconductor chip 800 in FIG. 19, the inventive concept is not limited thereto. The third semiconductor chip 800 may be disposed on the third metal wire 355 on which the adhesive layer 840 is formed.

The bonding pad 830 of the third semiconductor chip 800 may be formed of a metal such as aluminium (Al), copper (Cu), silver (Ag), or gold (Au), etc. as described above.

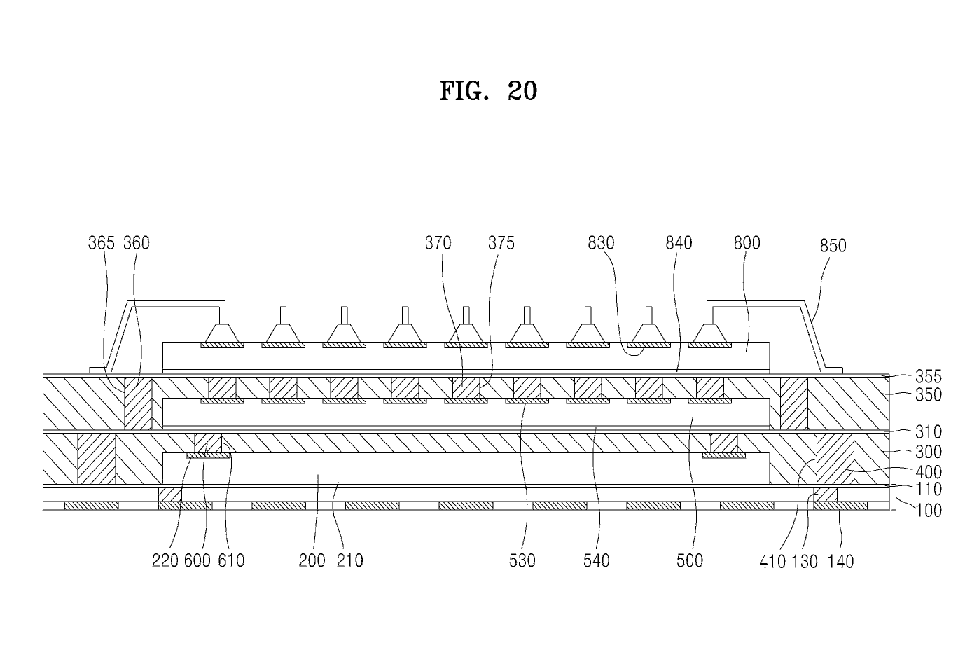

Referring to FIG. 20, the bonding wire 850 may be formed between the bonding pad 830 of the third semiconductor chip 800 and the third metal wire 355. The third semiconductor chip 800 may be electrically connected to the third metal wire 355 through the bonding wire 850.

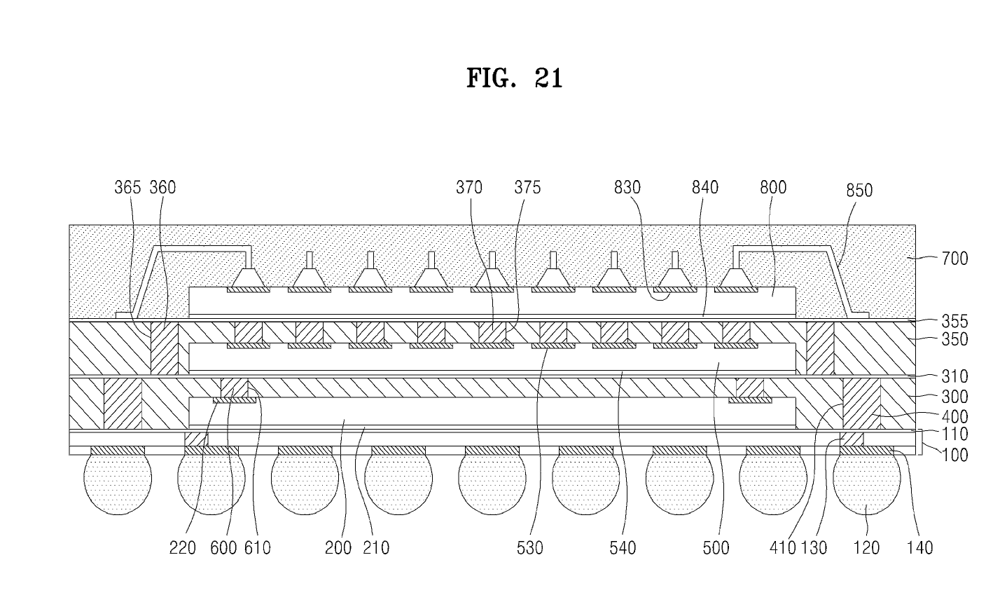

Referring to FIG. 21, the semiconductor package 1000c may be formed by coating the sealing member 700 like an EMC on the third semiconductor chip 800, the third metal wire 355, and the bonding wire 850, and forming the external connection terminal 120 like a solder ball in the bottom surface of the substrate 100.

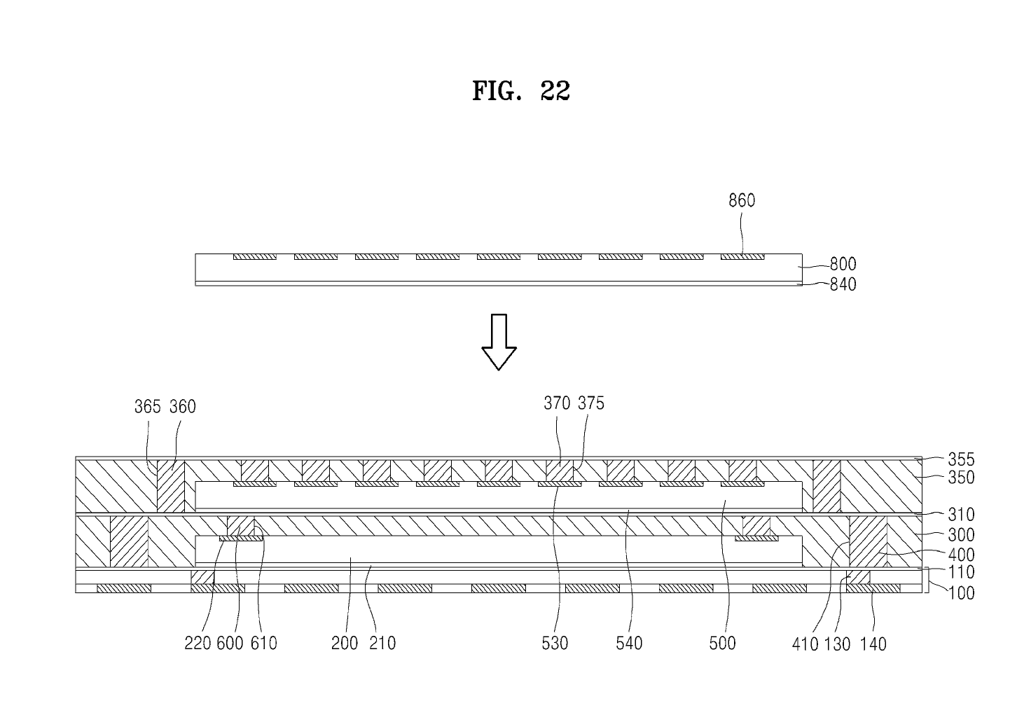

FIGS. 22 through 25 are cross-sectional views illustrating a method of manufacturing the semiconductor package 1000d of FIG. 6 according to an exemplary embodiment. The method of manufacturing the semiconductor package 1000c of FIG. 5 is the same as that of manufacturing the semiconductor package 1000a of FIG. 3 as described with reference to FIGS. 13 through 15, and thus the same descriptions will not be repeated, and differences therebetween will now be described.

Referring to FIG. 22, the third semiconductor chip 800 may be disposed on the third metal wire 355.

The third semiconductor chip 800 may include the adhesive layer 840 facing the third metal wire 355 in the non-active surface thereof and the bonding pad 860 in the active surface thereof.

Meanwhile, although the adhesive layer 840 is formed in the non-active surface of the third semiconductor chip 800 according to the thickness of the third semiconductor chip 800 in FIG. 22, the inventive concept is not limited thereto. The third semiconductor chip 800 may be disposed on the third metal wire 355 on which the adhesive layer 840 is formed.

The bonding pad 860 of the third semiconductor chip 800 may be formed of a metal such as aluminium (Al), copper (Cu), silver (Ag), or gold (Au), etc. as described above, and may act as a stop layer during a process of forming the sixth via hole 885.

The bonding pad 860 may be formed by plating electroless Ni or by plating electroless Ni and coating a solder metal on the plated electro less Ni. The plated electroless Ni may have a thickness of about 5 μm, and the solder metal may have a thickness of about 20 μm.

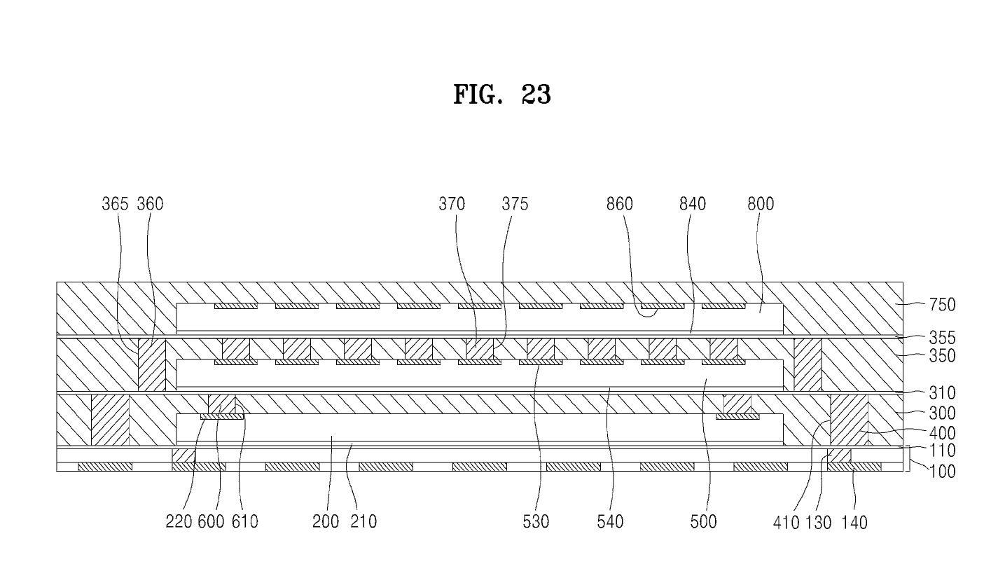

Referring to FIG. 23, the third insulation layer 750 may be formed to cover the third semiconductor chip 800 and at least a part of the third metal wire 355. The third insulation layer 750 may be formed by using the same method as that of forming the second insulation layer 350, and may be formed of the same material as that of the second insulation layer 350.

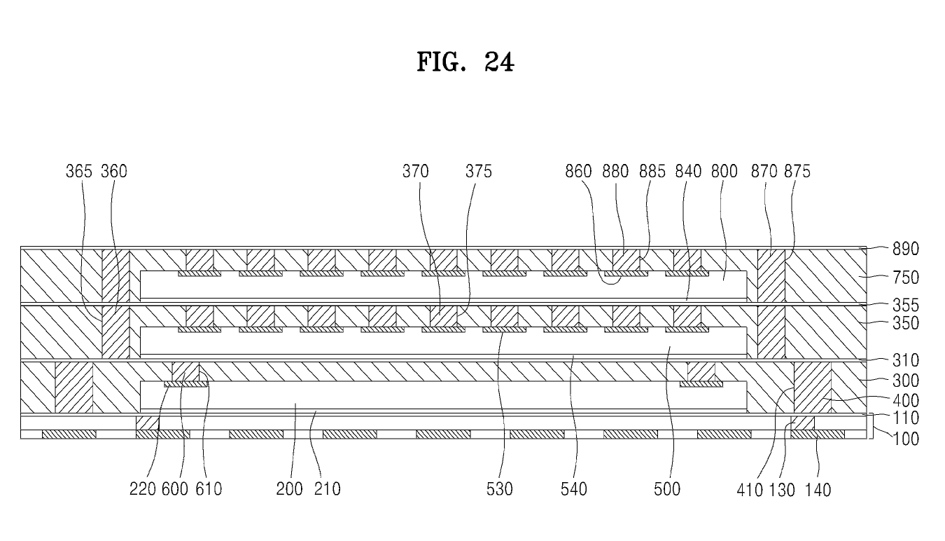

Referring to FIG. 24, the fifth via hole 875 and the sixth via hole 885 may be formed in the third insulation layer 350. The fifth via hole 875 may use a mechanical drilling process. The sixth via hole 885 may use a laser drilling process.

When the sixth via hole 885 is formed, since the bonding pad 860 is formed by plating electro less Ni or by plating electro less Ni and coating a solder metal on the plated electroless Ni, the bonding pad 860 acts as a laser stop layer during the laser drilling process, thereby preventing the third semiconductor chip 800 from being damaged.

Then, the fifth via 870 and the sixth via 880 may be formed by filling the fifth via hole 875 and the sixth via hole 885 with a conductive material. The conductive material may use Cu, Al, Ag, Au, Ni, and the like, and may be formed by using sputtering, a chemical vapour deposition, or electroplating.

Then, the fourth metal wire 890 may be formed in entire surfaces of the third insulation layer 750, the fifth via 870, and the sixth via 880. Thus, the third semiconductor chip 800 may be electrically connected to the third metal wire 355 through the fifth via 870 and the sixth via 880.

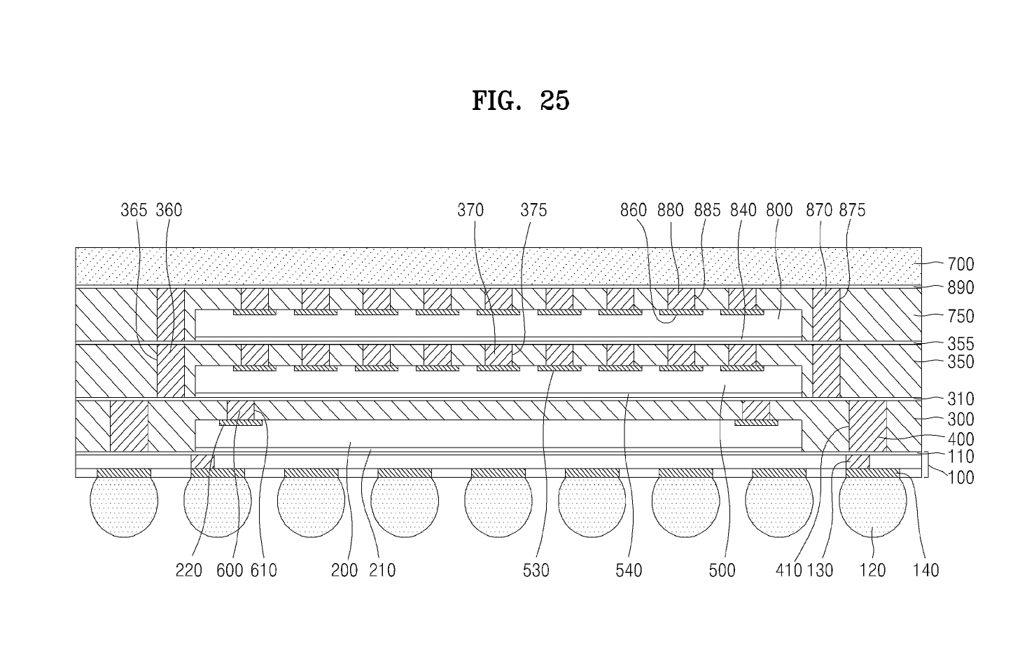

Referring to FIG. 25, the semiconductor package 1000d may be formed by coating the sealing member 700 like an EMC on the fourth metal wire 890 and forming the external connection terminal 120 like a solder ball in the bottom surface of the substrate 100.

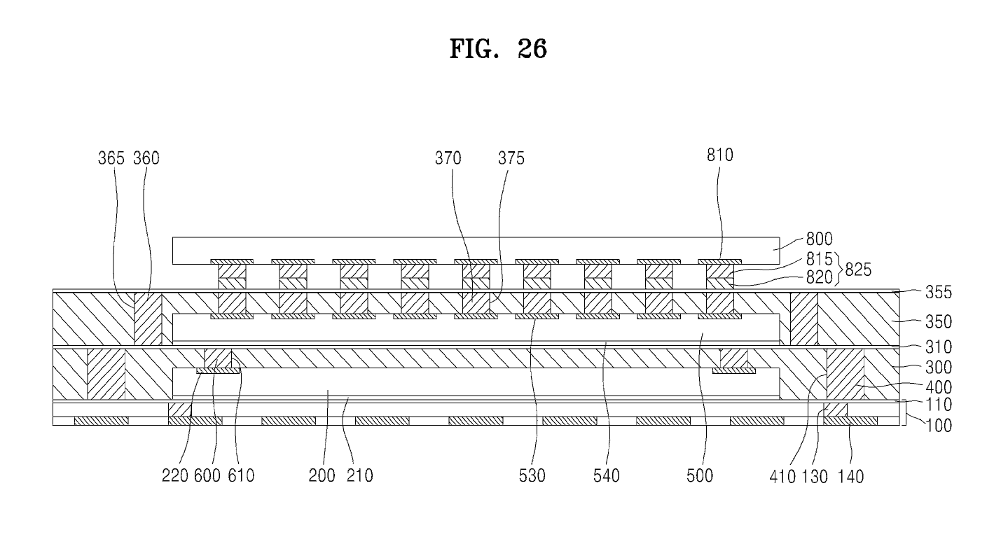

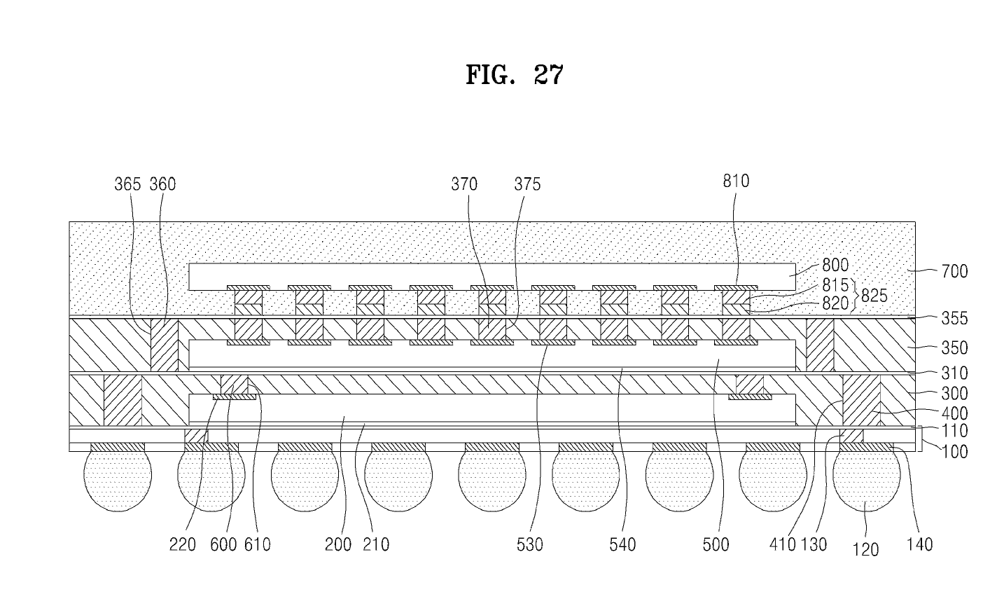

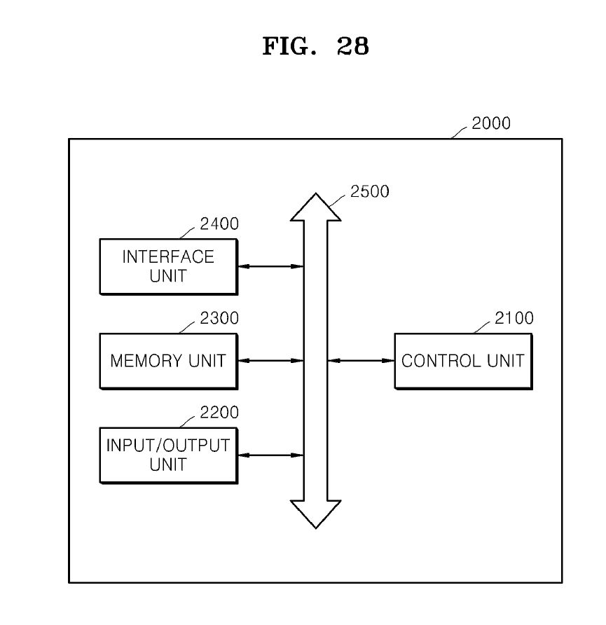

FIGS. 26 and 27 are cross-sectional views illustrating a method of manufacturing the semiconductor package 1000e according to an exemplary embodiment. The method of manufacturing the semiconductor package 1000e of FIG. 7 is the same as that of manufacturing the semiconductor package 1000a of FIG. 3 as described with reference to FIGS. 13 through 15, and thus the same descriptions will not be repeated, and differences therebetween will now be described.

Referring to FIG. 26, the third semiconductor chip 800 may be disposed on the third metal wire 355. The third semiconductor chip 800 may include the bonding pad 810 formed in the active surface thereof, and the bump 825 that electrically connects the bonding pad 810 to the third metal wire 355 and is adhered onto the third metal wire 355. The bump 825 may include the solder cap 820 or may include the copper filler 815 and the solder cap 820. The bump 825 may have a height greater than 30 μm for a gap filling.

Referring to FIG. 27, the third semiconductor chip 800 and the third metal wire 355 may be sealed by coating the sealing member 700 like an EMC, and may form the external connection terminal 120 like a solder ball in the bottom surface of the substrate 100.

FIG. 28 is a block diagram of an electrical and electronic apparatus 2000 including the semiconductor packages of FIGS. 1 and 3 through 7 according to an exemplary embodiment.

Referring to FIG. 28, the electrical and electronic apparatus 2000 includes a control unit 2100, an input/output unit 2200, a memory unit 2300, an interface unit 2400, and a bus 2500. The control unit 2100, the input/output unit 2200, the memory unit 2300, and the interface unit 2400 are connected to each other through the bus 2500. The term “unit” as used herein means a hardware component, such as a processor or circuit, and/or a software component that is executed by a hardware component such as a processor.

The control unit 2100 may include at least one processor for executing an order, for example, a microprocessor, a digital signal processor, or a microcontroller.

The input/output unit 2200 may receive data or signals from outside of the electrical and electronic apparatus 2000 or may output data or signals to out of the electrical and electronic apparatus 2000.

For example, the input/output unit 2200 may include a keyboard, a keypad, or a display device. The memory unit 2300 may store an order instructed by the control unit 2100, and may include various memories such as a DRAM and a flash memory. The interface unit 2400 may exchange data by communicating with a network.

In the electrical and electronic apparatus 2000 according to an exemplary embodiment, at least one of the control unit 2100, the memory unit 2300, and the interface unit 2400 may be formed of any one of the semiconductor packages 1000, 1000a, 1000b, 1000c, 1000d, and 1000e of FIGS. 1 and 3 through 7. That is, each of the semiconductor packages 1000, 1000a, 1000b, 1000c, 1000d, and 1000e of FIGS. 1 and 3 through 7, respectively, may be a semiconductor package for a memory chip or a logic chip that constitutes at least one of the control unit 2100, the memory unit 2300, and the interface unit 2400.

The electrical and electronic apparatus 2000 according to an exemplary embodiment can be used for mobile systems, for example, PDAs, portable computers, web tablets, wireless phones, mobile telephones, digital music generators, memory cards, and data transmission or receivers.

While the inventive concept has been particularly shown and described with reference to exemplary embodiments thereof, it will be understood that various changes in form and details may be made therein without departing from the spirit and scope of the following claims.

1. A semiconductor package comprising:
a substrate;
a first metal wire on a top surface of the substrate;
a first semiconductor chip disposed on the substrate;
a first insulation layer which covers the first semiconductor chip and at least a part of the substrate;
a second metal wire formed on the first insulation layer;
a first via formed in the first insulation layer, wherein the first via electrically connects the second metal wire and the first metal wire; and
a second semiconductor chip electrically connected to the second metal wire and disposed on the second metal wire.

2. The semiconductor package of claim 1, further comprising: a second via formed in the first insulation layer, wherein the second via electrically connects the first semiconductor chip and the second metal wire.

3. The semiconductor package of claim 2, wherein the first semiconductor chip comprises:
a non-active surface comprising an adhesive layer, wherein the adhesive layer faces the substrate; and
an active surface comprising a bonding pad, wherein the bonding pad is electrically connected to the second metal wire through the second via.

4. The semiconductor package of claim 3, wherein the bonding pad is plated with an electroless Ni plating.

5. The semiconductor package of claim 4, further comprising a solder metal on the electroless Ni plating.

6. The semiconductor package of claim 4, wherein the electro less Ni plating has a thickness of about 5 μm.

7. The semiconductor package of claim 4, wherein the solder metal has a thickness of about 20 μm.

8. The semiconductor package of claim 1, wherein the second semiconductor chip comprises:
a bonding pad formed in an active surface of the second semiconductor chip; and
a bump, which electrically connects the bonding pad to the second metal wire and which is adhered to the second metal wire.

9. The semiconductor package of claim 8, wherein the bump comprises a copper filler and a solder cap.

10. The semiconductor package of claim 1, further comprising:
a second insulation layer which covers the second semiconductor chip and at least a part of the second metal wire;
a third metal wire formed on a top surface of the second insulation layer; and
a third via formed in the second insulation layer, wherein the third via electrically connects the third metal wire and the second metal wire.

11. The semiconductor package of claim 10, further comprising: a fourth via formed in the second insulation layer, wherein the fourth via electrically connects the second semiconductor chip and the third metal wire.

12. The semiconductor package of claim 11, wherein the second semiconductor chip comprises:
a non-active surface comprising an adhesive layer, wherein the adhesive layer faces the second metal wire; and
an active surface comprising a bonding pad, wherein the bonding pad is electrically connected to the third metal wire through the fourth via.

13. The semiconductor package of claim 1, wherein the second semiconductor chip comprises:
a non-active surface comprising an adhesive layer, wherein the adhesive layer faces the second metal wire; and
an active surface comprising a bonding pad, wherein the bonding pad is electrically connected to the second metal wire through a bonding wire.

14. The semiconductor package of claim 1, wherein the second metal wire is made of Ni and Cu or of Cu.

15. The semiconductor package of claim 10, further comprising:
a third semiconductor chip electrically connected to the third metal wire and disposed on the third metal wire;
a third insulation layer which covers the third semiconductor chip and at least a part of the third metal wire;
a fourth metal wire formed on a top surface of the third insulation layer; and
a fifth via formed in the third insulation layer, wherein the fifth via electrically connects the fourth metal wire and the third metal wire.

16. The semiconductor package of claim 1, wherein a portion of the first metal wire is disposed between the first insulation layer and the part of the substrate covered by the first insulation layer.

17. A semiconductor package comprising:
a substrate;
a metal wire formed on a top surface of the substrate;
a first semiconductor chip disposed on at least a portion of a top surface of the metal wire;
a first insulation layer formed to cover the first semiconductor chip and at least a part of the substrate, wherein the first insulation layer is formed so that the first semiconductor chip is embedded in the first insulation layer;
a second semiconductor chip disposed on the first insulation layer and electrically connected to the metal wire; and
a via formed in the first insulation layer, wherein the via electrically connects the first semiconductor chip to the metal wire.

18. (canceled)

19. (canceled)
